(19) United States
(12) Patent Application Publication
(10) Pub. No.: US 2006/0228633 A1
(43) Pub. Date: Oct. 12, 2006

(54) Method of resolving phase conflicts in an alternating phase shift mask and the alternating phase shift mask

(76) Inventor: Shu-Hao Hsu, Yun-Lin Hsien (TW)

Correspondence Address: NORTH AMERICA INTELLECTUAL PROPERTY CORPORATION, P.O. BOX 506, MERRIFIELD, VA, 22116, US

(21) Appl. No.: 10/907,589

(22) Filed: Apr. 7, 2005

(51) Int. Cl. G06F 17/50; G03F 1/00; G03C 5/00

(52) U.S. Cl. 430/5; 716/19; 716/21; 430/30

(57) ABSTRACT

A method of resolving phase conflict in an alternating phase shift mask and the alternating phase shift mask are disclosed, which are characterized by that a transparent slit region is formed on an non-transparent region placed in a phase conflict area encountered at layout in an alternating phase shift mask and the transparent slit region and the transparent region adjacent to the non-transparent region have a phase difference, thereby a phase conflict problem is resolved.

### BACKGROUND OF THE INVENTION

1. Field of the Invention

The present invention relates to a mask, and particularly to an alternating phase shift mask (Alt-PSM) and a method of resolving phase conflicts in an Alt-PSM.

2. Description of the Prior Art

In integrated circuit making processes, a lithographic process has been an important technique. Alt-PSM is one of the techniques to enhance resolution in the next generation of lithography.

Please refer to FIG. 1, which is a structural diagram of a conventional Alt-PSM 10. As shown in FIG. 1, a fully opaque material such as chrome is used in a non-transparent region 12 of the Alt-PSM 10, and the non-transparent region 12 is flanked by transparent regions 14, 16. Both of the transparent regions 14, 16 are made of quartz. The thickness of the transparent region 14 is approximately 2280 angstroms less than that of the transparent region 16. Therefore, light passing through the transparent region 14 has a phase shift of 180 degrees relative to light passing through the thicker transparent region 16, which results in destructive interference. Consequently, during the lithographic process, a dark unexposed region falls on an area of a resist layer and is located below the non-transparent region 12 of the Alt-PSM 10.

However, the Alt-PSM technique easily encounters a phase conflict problem in phase assignment. When a circuit pattern has both of a set of an even number of lines and a set of an odd number of lines in one area, the corresponding Alt-PSM used in the lithographic process in the manufacture of the circuit encounters a phase conflict problem. For example, as shown in FIG. 2, in a conventional Alt-PSM 20, a plurality of non-transparent regions 26 are in a linear shape and respectively posited between a plurality of transparent regions 22 (180 degree) and a plurality of transparent regions 24 (0 degree) alternatively arranged, resulting a good resolution and line features. However, for the non-transparent region 28, a phase conflict occurs when the phase assignment is made to the transparent region 24 surrounding the non-transparent region 28, and, accordingly, a regular alternative assignment of phases 0 degree and 180 degree to the transparent regions cannot be achieved, and accordingly a phase conflict occurs. One of known methods is to take the mask as two sections. One is the section 32 having the even number of lines, and the other is the section 34 having the odd number of lines. These two sections separately use their own suitable alternating phase shift arrangement. Thus, there are two pattern sections in one mask. After an exposure is performed on a resist layer using the mask, a dark line may be produced on the resist layer at the position corresponding to the border between the two pattern sections. A second lithographic process using another mask is required to remove the dark line. Therefore, the manufacturing process is relatively complicated.

In other respect, a paper entitled “Super-resolution enhancement method with phase-shifting mask available for random patterns” is reported by Akio Misaka et al. in 2002 Symposium On VLSI Technology Digest of Technical Papers, pages 200 to 201, IEEE publication. A conventional centerline phase shift mask (CL-PSM) for enhancing resolution is described. FIG. 3 shows the principle for enhancing the image of a line pattern. L is the line width of the Cr mask. W is the width of the aperture of the shifter. lc(L) is the intensity at the center of the line pattern. It increases with decreasing line width L. Thus, the contrast of the aerial image decreases for fine line pattern. lo(W) is the intensity at the center of a phase shifting aperture. The contrast is maximized by a phase shifting aperture included in the line pattern on condition that lo(W)=lc(L). The width of the phase shifting aperture included in the line pattern can be controlled in order to compensate for the degradation in contrast. Akio Misaka et al. found that CL-PSM enhanced the depth of focus (DOF) more than alt-PSM.

However, those prior arts do not mention how to resolve the phase conflict problem. Therefore, when a single alt-PSM is wanted to be used in the manufacturing of a circuit having a pattern of uneven lines, such as with a set of an even number of lines in one area and a set of an odd number of lines in an adjacent area, it still needs a good method to resolve the phase conflict problem.

### SUMMARY OF INVENTION

An object of the present invention is to provide a method of resolving a phase conflict in an Alt-PSM, such that an Alt-PSM can be suitable used in the manufacture of a circuit with lines of various lengths without the phase conflict problem as mentioned above.

Another object of the present invention is to provide an Alt-PSM suitable used in the manufacture of a circuit without the phase conflict problem.

The method of resolving phase conflicts in an Alt-PSM according to the present invention comprises the following steps. First, an alternating phase shift mask layout design having an area with a phase conflict is found, wherein the area with a phase conflict comprises a first non-transparent region and a first transparent region and a second transparent region on the two sides of the first non-transparent region, respectively. Next, the first non-transparent region is allowed to have a transparent slit region, wherein the transparent slit region and both of the first transparent region and the second transparent region have a phase difference.

The Alt-PSM according to the present invention comprises a transparent substrate; at least one third transparent region on the transparent substrate; at least one fourth transparent region on the transparent substrate and alternatively arranged with the third transparent region, wherein the third transparent region and the fourth transparent region have a phase difference; a plurality of fourth non-transparent regions respectively arranged between the third transparent region and the fourth transparent region; and at least one fifth non-transparent region surrounded by the third or fourth transparent region, wherein the fifth non-transparent region has a transparent slit region, and the transparent slit region and the third or fourth transparent region surrounding the fifth non-transparent region have a phase difference.

The advantages of using a method of resolving phase conflicts in an Alt-PSM and the Alt-PSM in the manufacture of a circuit having lines of uneven lengths are that only one Alt-PSM is needed, the phase conflict problem will not happen, and dark lines due to different pattern borders will not happen such that a second lithography process is not required. Accordingly, the manufacturing processes are relatively simplified for circuits or electrical elements utilizing the method or the mask of the present invention.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic structural diagram of a conventional Alt-PSM.

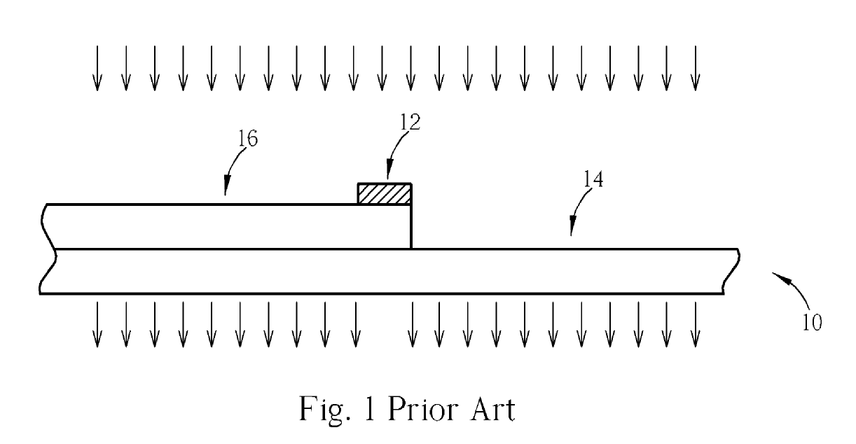

FIG. 2 is a schematic diagram showing a phase conflict occurring in a conventional Alt-PSM.

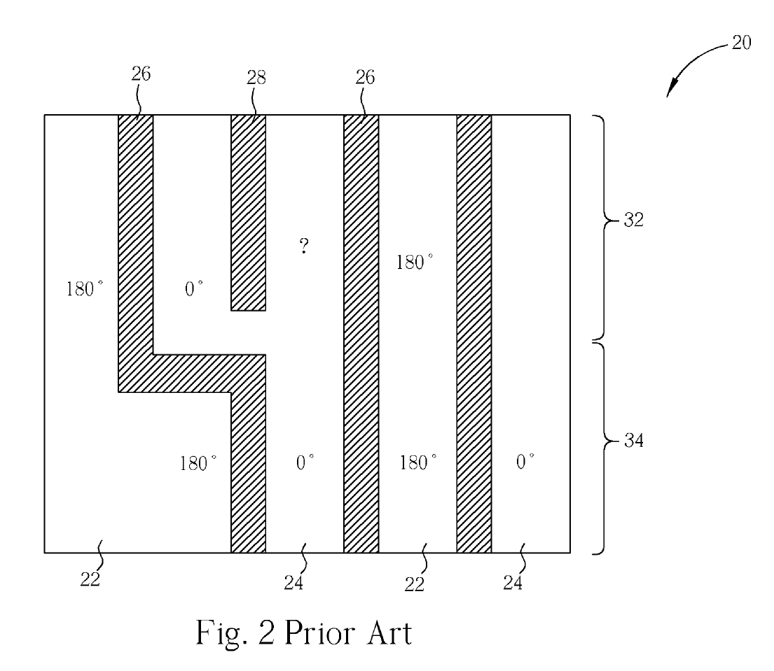

FIG. 3 is a schematic structural diagram of a conventional centerline phase shift mask.

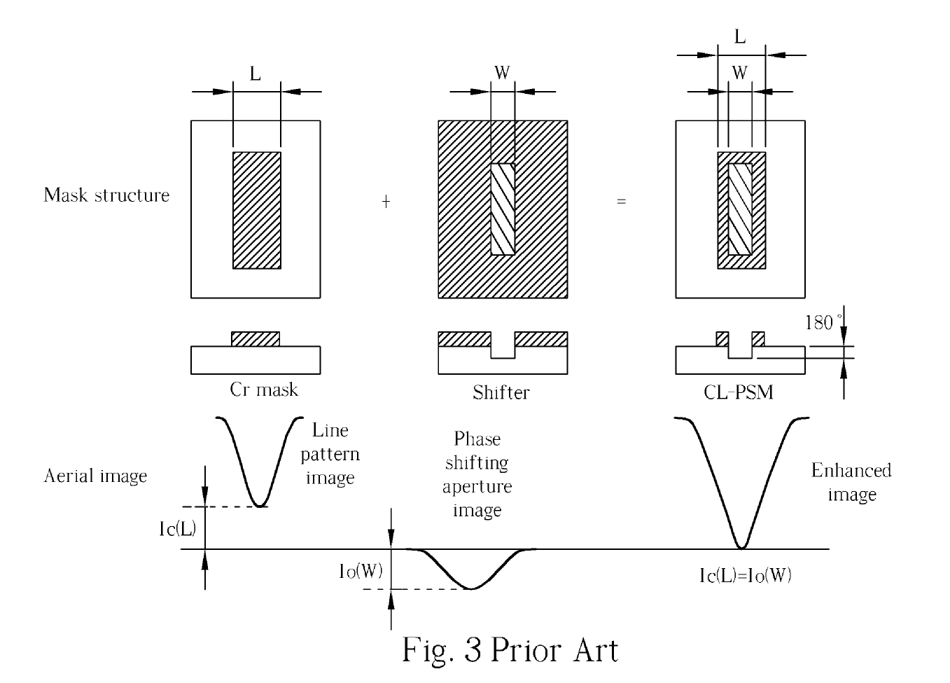

FIG. 4 is a structural diagram of an Alt-PSM according to the present invention.

FIG. 5 is another structural diagram of an Alt-PSM according to the present invention.

FIG. 6 shows cross section views of the Alt-PSM of FIG. 4 along line A-A′ and line B-B′ of FIG. 4.

FIG. 7 shows cross section views of the Alt-PSM of FIG. 4 along line A-A′ and line B-B′ of FIG. 4, according to another embodiment.

### DETAILED DESCRIPTION

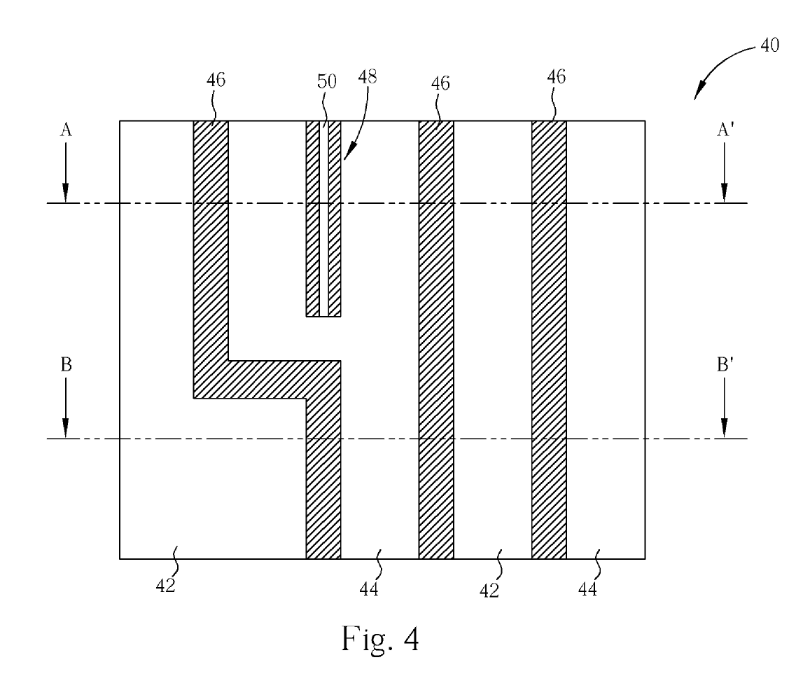

Please refer to FIGS. 4 to 6 showing the method of resolving phase conflicts in an Alt-PSM and the Alt-PSM according to the present invention. The method of resolving phase conflicts in an Alt-PSM is characterized by, when a circuit pattern is to be made with a mask in a lithography process, and the circuit pattern causes the layout of Alt-PSM to encounter a phase conflict in a an area, with regard to the mask, a transparent slit region is formed in the non-transparent region surrounded by a transparent region where a phase conflict occurs, and the transparent slit region and the transparent region (i.e. the transparent region occurs a phase conflict) is made to have a phase difference, to resolve the phase conflict problem.

FIG. 4 is a schematic diagram showing the Alt-PSM 40 according to the present invention. The Alt-PSM uses a transparent material as a substrate, for example, quartz. A plurality of transparent regions 42 and a plurality of transparent regions 44 are formed on the transparent substrate and alternatively arranged. The transparent regions 42 and the transparent regions 44 have a phase difference, such as substantially 180 degree. The phase difference can be attained by forming a thickness difference on the transparent substrate or using a phase shifting material layer according to conventional methods. Between the transparent region 42 and the transparent region 44, there is a non-transparent region 46 with a linear pattern, which may comprise a conductive layer, such as chrome. In the Alt-PSM 40 according to the present invention, a non-transparent region 48 with a linear pattern exists in the transparent region 44. This transparent region 44 will encounters a phase conflict problem according to conventional techniques, while the problem is solved in the present invention. In the present invention, a transparent slit region 50 is formed in the non-transparent region 48, both having a same longitudinal direction. The transparent slit region 50 and the transparent region 44 have a phase difference, such as substantially 180 degree.

The width of the transparent slit region 50 is set to be a width such that when the exposure is performed using the mask, the portion of the resist layer at the corresponding position under the transparent slit region 50 does not react to the light. Accordingly, the width of the transparent slit region 50 can be different according to the light exposure process, depending on parameters such as the light wavelength, the number of aperture, the exposing machine, while with a size in the range of sub-resolution. The resolution (R) is defined as follows:
R(μm)=k₁λ/NA
wherein, λ is the light wavelength used for the exposure, NA is the numerical aperture of the lens, and k₁ is a constant depending on the resist. The light passing the transparent slit region is controlled to be with an energy being less than the energy threshold value required by the light-receiving layer, such as a resist layer, to react. Accordingly, the portion of resist under the transparent slit region 50 is not affected by the light. Moreover, the transparent slit region 50 and the transparent region 44 surrounding the non-transparent region 48 have a phase difference, resulting in destructive interference upon exposing to the light, such that the resist layer under the non-transparent region 48 (including the transparent slit region 50) is not exposed to the light. Therefore, the phase conflict will not occur in this region, and a better line feature can be obtained.

In the Alt-PSM shown in FIG. 4, the non-transparent region 48 is between two non-transparent regions 46, and all the lines shown has the same longitudinal direction. Whereas, in the present invention, the arrangement of the non-transparent region positioned in the original phase conflict area is not limited to in a particular direction, and can be such as in a longitudinal, lateral, or oblique direction or further connected to an adjacent non-transparent region. Each linear pattern may have a bend or be a curve.

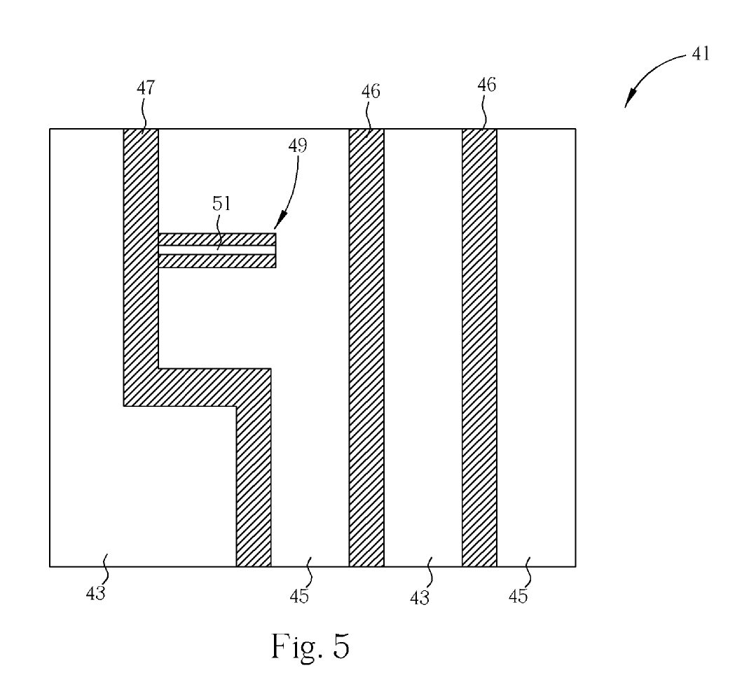

Please refer to FIG. 5, showing another structural diagram of an Alt-PSM 41 according to the present invention. A plurality of transparent regions 43 and a plurality of transparent regions 45 are formed on the transparent substrate and alternatively arranged. Between the transparent region 43 and the transparent region 45, there is a non-transparent region 47 with a linear pattern. A non-transparent region 49 with a linear pattern exists in the transparent region 45 and is arranged with its longitudinal direction pointing to the lateral direction of the non-transparent region 47 and connected to the non-transparent region 47. A transparent slit region 51is formed in the non-transparent region 49. The transparent slit region 51 and the transparent region 45 have a phase difference, such as substantially 180 degree. Thus, a phase conflict problem encountered in a conventional Alt-PSM can be solved.

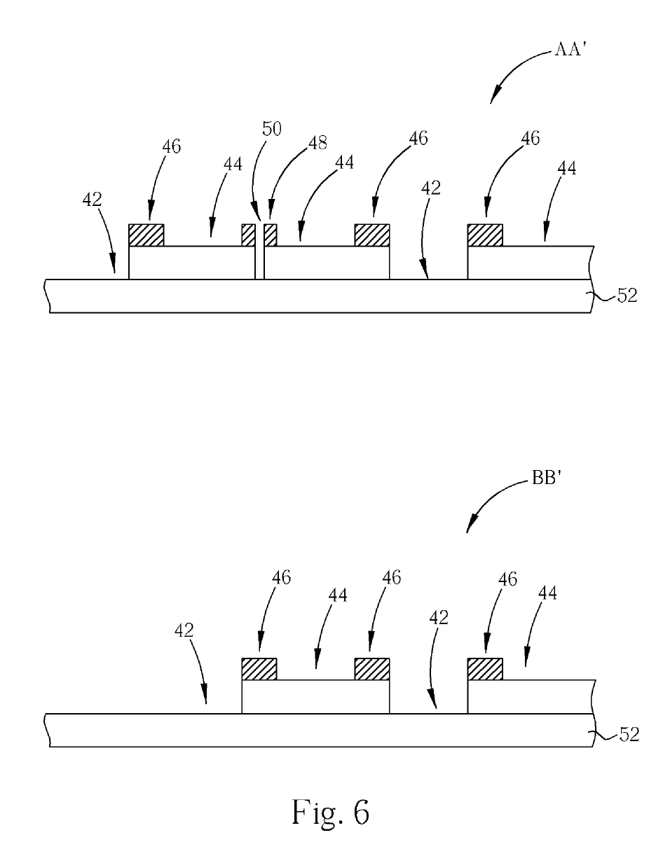

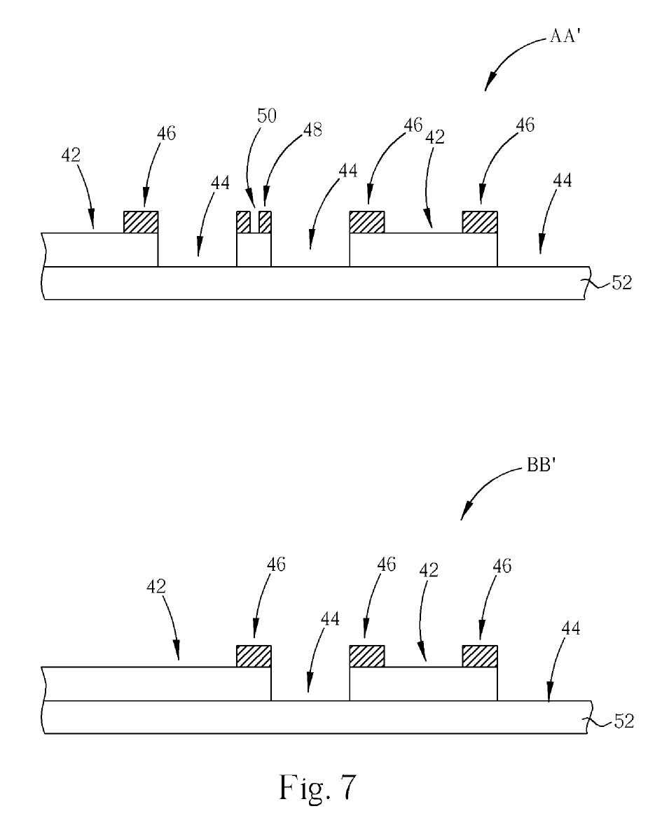

The transparent regions, the non-transparent regions, and the transparent slit regions of the Alt-PSM according to the present invention are not limited to a particular phase. It is preferred that the two adjacent transparent regions have a phase difference of substantially 180 degree, and the transparent slit region and the adjacent transparent regions have a phase difference of substantially 180 degree. For example, one embodiment is shown in FIG. 6. FIG. 6 shows cross section views of the Alt-PSM of FIG. 4 along line A-A′ and line B-B′ of FIG. 4. The phase of the transparent region 42 is 0 degree. The phase of the transparent region 44 is 180 degree. The phase of the transparent slit region 50 positioned in the non-transparent region 48 surrounded by the transparent region 44 is 0 degree. Another embodiment is shown in FIG. 7. FIG. 7 shows cross section views of the Alt-PSM of FIG. 4 along line A-A′ and line B-B′ of FIG. 4. The phase of the transparent region 42 is 180 degree. The phase of the transparent region 44 is 0 degree. The phase of the transparent slit region 50 positioned in the non-transparent region 48 surrounded by the transparent region 44 is 180 degree. The fabrication of the Alt-PSM according to the present invention may achieved using conventional mask making techniques, such as film deposition, lithography, etching and in accordance with the design size of the mask.

The method of resolving phase conflicts in an Alt-PSM and the Alt-PSM according to the present invention can resolve the phase conflict problem encountered for manufacturing circuits with a pattern of lines with uneven lengths. For example, regarding to a conventional circuit with a pattern of two adjacent areas, one area having a set of odd number of lines and the other area having a set of even number of lines, causing a phase conflict in a conventional Alt-PSM, the phase conflict problem can be easily resolved using the method of resolving phase conflicts in an Alt-PSM and the Alt-PSM according to the present invention. Only one Alt-PSM is used. Moreover, a dark line due to a pattern border resulting from an improper lithography will not happen, such that a second lithography process is not required. Accordingly, the manufacturing processes are relatively simplified.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of resolving phase conflicts in an alternating phase shift mask, comprising the steps of:
finding an alternating phase shift mask layout design having an area with a phase conflict, wherein the area with a phase conflict comprises a first non-transparent region and a first transparent region and a second transparent region on the two sides of the first non-transparent region, respectively; and
allowing the first non-transparent region to have a transparent slit region wherein the transparent slit region and both of the first transparent region and the second transparent region have a phase difference.

2. The method of claim 1, wherein the first non-transparent region has a linear shape, and the transparent slit region has a longitudinal direction in the same direction of the longitudinal direction of the first non-transparent region.

3. The method of claim 1, wherein the first transparent region and the second transparent region have a same phase.

4. The method of claim 1, wherein the phase difference is substantially 180 degree.

5. The method of claim 1, wherein the first non-transparent region is between a linear second non-transparent region and a linear third non-transparent region.

6. The method of claim 5, wherein the longitudinal direction of the first non-transparent region is substantially in the same direction as the longitudinal direction of the second non-transparent region or the third non-transparent region.

7. The method of claim 5, wherein the longitudinal direction of the first non-transparent region is not in the same direction as the longitudinal direction of the second non-transparent region or the third non-transparent region.

8. The method of claim 7, wherein the first non-transparent region is connected to one of the second non-transparent region and the third non-transparent region.

9. An alternating phase shift mask, comprising:
a transparent substrate;
at least one third transparent region on the transparent substrate;
at least one fourth transparent region on the transparent substrate and alternatively arranged with the third transparent region, wherein the third transparent region and the fourth transparent region have a phase difference;
a plurality of fourth non-transparent regions respectively arranged between the third transparent region and the fourth transparent region; and
at least one fifth non-transparent region surrounded by the third or fourth transparent region, wherein the fifth non-transparent region has a transparent slit region, and the transparent slit region and the third or fourth transparent region surrounding the fifth non-transparent region have a phase difference.

10. The mask of claim 9, wherein the third transparent region and the fourth transparent region substantially have a phase difference of 180 degree.

11. The mask of claim 9, wherein the fourth non-transparent regions and the fifth non-transparent region have a linear shape.

12. The mask of claim 11, wherein the longitudinal direction of the fifth non-transparent region is substantially in the same direction as the longitudinal direction of the fourth non-transparent regions.

13. The mask of claim 11, wherein the longitudinal direction of the fifth non-transparent region is not in the same direction as the longitudinal direction of the fourth non-transparent regions.

14. The mask of claim 13, wherein the fifth non-transparent region is connected to an adjacent fourth non-transparent region.

15. The mask of claim 9, wherein the transparent substrate comprises quartz.

16. The mask of claim 9, wherein the fourth and fifth non-transparent region comprise chromium.
